(19) United States
(12) Patent Application Publication
(10) Pub. No.: US 2021/0118673 A1
(43) Pub. Date: Apr. 22, 2021

(54) METHOD FOR FORMING A CHEMICAL GUIDING STRUCTURE ON A SUBSTRATE AND CHEMO-EPITAXY METHOD

(71) Applicant: Commissariat à l'Energie Atomique et aux Energies Alternatives, PARIS (FR)

(72) Inventors: Raluca TIRON, GRENOBLE CEDEX 09 (FR); Tommaso-Jacopo GIAMMARIA, GRENOBLE CEDEX 09 (FR)

(21) Appl. No.: 17/072,631

(22) Filed: Oct. 16, 2020

(30) Foreign Application Priority Data
Oct. 16, 2019 (FR) 1911542

(51) Int. Cl. H01L 21/027; H01L 21/02; H01L 21/308; B81C 1/00; C08L 53/00; H01L 21/3065

(52) U.S. Cl. CPC H01L 21/0273; H01L 21/02118; H01L 21/3086; H01L 21/0338; H01L 21/02293; C08L 53/00; H01L 21/3065; B81C 1/00031

(57) ABSTRACT

A method for forming a chemical guiding structure for self-assembling organic nano-objects by chemo-epitaxy, the method including forming on a substrate sacrificial patterns having a critical dimension in a plane parallel to the substrate; forming on the substrate, between the sacrificial patterns, a first pattern made of a first polymer material, the first polymer material having a first chemical affinity with respect to the organic nano-objects; partially etching the sacrificial patterns so as to reduce the critical dimension of the sacrificial patterns, the sacrificial patterns being etched selectively with respect to said first pattern using a first wet etching method; forming on the substrate, in areas created by the partial etching of the sacrificial patterns, second patterns made of a second polymer material, the second polymer material having a second chemical affinity with respect to the organic nano-objects, different from the first chemical affinity; and removing the sacrificial patterns.

### CROSS REFERENCES TO RELATED APPLICATIONS

This application claims priority to French Patent Application No. 1911542, filed Oct. 16, 2019, the entire content of which is incorporated herein by reference in its entirety.

### FIELD

The present invention relates to a method for forming a chemical guiding structure intended for the directed self-assembly of organic nano-objects by chemo-epitaxy. The present invention also relates to a method for chemo-epitaxy from a chemical guiding structure.

### BACKGROUND

Directed self-assembly (DSA) of block copolymers is an emerging lithography technique making it possible to form patterns of critical dimension less than 30 nm. This technique constitutes a less expensive alternative to extreme ultraviolet (EUV) lithography and to e-beam lithography.

Known methods of self-assembly of block copolymers may be grouped into two categories: grapho-epitaxy and chemo-epitaxy.

Grapho-epitaxy consists in forming primary topographic patterns called guides on the surface of a substrate, these patterns delimiting areas inside of which a layer of block copolymer is deposited. The guiding patterns make it possible to control the organisation of the copolymer blocks to form secondary patterns of greater resolution inside these areas.

Chemo-epitaxy consists in modifying the chemical properties of certain regions of the surface of the substrate, to guide the organisation of the block copolymer deposited later on this surface. The chemical modification of the substrate may notably be obtained by grafting a polymer neutralisation layer. Then, this neutralisation layer is patterned in order to create a chemical contrast on the surface of the substrate. Thus, the regions of the substrate not covered by the neutralisation layer have a preferential chemical affinity for one of the blocks of the copolymer, whereas the regions of the substrate covered by the neutralisation layer have an equivalent chemical affinity for all of the blocks of the copolymer. The patterning of the neutralisation layer is conventionally obtained by a step of optical or e-beam lithography.

Chemo-epitaxy may also be used for other types of organic nano-objects and notably bio-inspired systems, such as proteins, DNA strands or DNA origamis. The examples of method described hereafter are applied to block copolymers but could apply in an analogous manner for the self-assembly of proteins, DNA strands or instead DNA origamis.

To guarantee an assembly of the block copolymer with a minimum of organisation defects, the regions of the substrate having a preferential affinity for one of the blocks are typically of width W equal to the width of the domain of this block, the latter being equal to half of the natural period L₀ of the copolymer (W=0.5*L₀) or equal to one and a half times this natural period (W=1.5*L₀). Moreover, the regions of the substrate having a preferential affinity are typically separated two by two by a distance L_{S} equal to a multiple integer of the period L₀ (L_{S}=n*L₀, with n a non-zero natural integer called pitch multiplication factor).

The article of C-C. Liu et al. entitled [“Integration of block copolymer directed assembly with 193 immersion lithography”, J. Vac. Sci. Technol., B 28, C6B30-C6B34, 2010] describes a chemo-epitaxy method comprising the formation of a chemical guiding structure on the surface of a substrate. The chemical guiding structure is composed of guiding patterns made of a polymer having a preferential affinity for one of the blocks of the copolymer and a film of random copolymer grafted onto the substrate outside of the patterns, in a so-called background region. The random copolymer is neutral with respect to the block copolymer, such that the domains of the copolymer are (after assembly) oriented perpendicularly to the substrate. The chemical guiding structure is intended to direct the self-assembly of the block copolymer PS-b-PMMA (polystyrene-block-polymethylmethacrylate). The guiding patterns, in the form of lines, are comprised of cross-linked polystyrene (X-PS). The random copolymer, grafted between the lines, is PS-r-PMMA.

With reference to FIG. 1, this chemo-epitaxy method firstly comprises the formation of a film of cross-linked polystyrene 11 on a silicon substrate 10. A mask comprised of resin patterns 12 is next formed on the film of cross-linked polystyrene 11, by optical lithography (typically with 193 nm immersion). Then, the resin patterns 12 are etched by means of an oxygen-based plasma until reaching a width W of around half of the natural period L₀ of the block copolymer. During this step, the film of cross-linked polystyrene 11 is also etched through the mask 12 by the plasma. This etching step is commonly called “trim etch”. Patterns of cross-linked polystyrene, in the form of parallel lines 11′, are thus formed on the substrate 10. After the “trim etch” step, the lines of polystyrene 11′ have a width W equal to 15 nm and are spaced apart two by two by a distance L_{S} equal to 90 nm. After removal of the resin mask 12, the substrate 10 is covered with a solution comprising the graftable random copolymer, then the random copolymer is grafted between the lines 11′ to form a neutralisation layer 13. Finally, a layer of PS-b-PMMA 14 is deposited then assembled on the chemical guiding structure composed of the lines of polystyrene 11′ and the neutralisation layer 13.

The document [“Three-Tone Chemical Patterns for Block Copolymer Directed Self-Assembly”, L. D. Williamson et al., ACS Appl. Mater. Interfaces, 8, pp. 2704-2712, 2016] describes an alternative of the chemo-epitaxy method according to FIG. 1.

In this alternative of the method, illustrated by FIG. 2, the “trim etch” step is accomplished so as to only partially etch the film of cross-linked polystyrene 11 outside of the patterns 12 and to obtain lines of polystyrene 11′ of trapezoidal section. Each line of polystyrene 11′ then comprises an upper face 11a covered by a resin pattern 12, and on either side of the upper face 11a, two oblique flanks 11b which have been exposed to oxygen plasma. Exposure to plasma having the effect of oxidising the polystyrene, the oblique flanks 11b of the lines of polystyrene 11′ have a preferential affinity for the PMMA block, whereas the upper face 11a of the lines of polystyrene 11′ (protected by the resin pattern 12 during the plasma etching) conserve a preferential affinity for the PS block.

The chemical guiding structure, obtained after removal of the resin patterns 12 and formation of a neutralisation layer 13, thus comprises:
first guiding patterns made of non-modified polystyrene, corresponding to the upper face 11a of the lines of polystyrene 11′ and having a preferential affinity for the PS block;
second guiding patterns made of modified (i.e. oxidised) polystyrene, corresponding to the oblique flanks 11b of the lines of polystyrene 11′ and having a preferential affinity for the PMMA block, each of the first guiding patterns 11a being bordered by two second guiding patterns 11b; and
the neutralisation layer 13 arranged in the background region, between the different groups of guiding patterns.

This chemical guiding structure is called “three-tone” because it has three different chemical affinities for the assembly of the block copolymer 14: PS affine, PMMA affine and neutral. Due to the higher number of guiding patterns in the three-tone guiding structure, the assembly kinetic of the block copolymer is increased and the number of organisation defects is reduced.

In the chemo-epitaxy method of FIG. 1, and even more in that of FIG. 2, it is difficult to control precisely the width or critical dimension W of the guiding patterns in strip form. The step of “trim etching” by an oxygen plasma is in fact awkward to implement, in particular with such narrow resin patterns. Moreover, in the method of FIG. 2, the affinity of the second guiding patterns 11b is dictated by the oxygen plasma treatment. It is thus not possible to choose the chemical affinity of these guiding patterns freely.

### SUMMARY

There exists a need to provide a method for forming a chemical guiding structure enabling better dimensional control of the guiding patterns and a free choice of the chemical affinities with respect to the organic nano-objects to assemble, such as the domains of a block copolymer.

According to a first aspect of the invention, this need tends to be satisfied by providing a method for forming a chemical guiding structure intended for the self-assembly of organic nano-objects by chemo-epitaxy, this method comprising the following steps:
forming on a substrate sacrificial patterns having a critical dimension in a plane parallel to the substrate;
forming on the substrate, between the sacrificial patterns, at least one first pattern made of a first polymer material, the first polymer material having a first chemical affinity with respect to the organic nano-objects;
partially etching the sacrificial patterns so as to reduce the critical dimension of the sacrificial patterns, the sacrificial patterns being etched selectively with respect to said at least one first pattern using a first wet etching method;
forming on the substrate, in areas created by the partial etching of the sacrificial patterns, second patterns made of a second polymer material, the second polymer material having a second chemical affinity with respect to the organic nano-objects, different from the first chemical affinity; and
removing the sacrificial patterns.

In methods of the prior art, etching of the resin patterns, called “trim etch”, is employed to delimit guiding patterns in a polymer layer (X-PS) deposited beforehand. Conversely, in the method according to the first aspect of the invention, the selective etching of the sacrificial patterns serves to create (i.e. to free) areas in which a polymer material is later deposited to form new guiding patterns. In other words, only the sacrificial patterns are etched in the method according to the first aspect of the invention. The polymer material may be chosen freely as a function of the affinity desired for the new guiding patterns.

A wet etching method is employed to etch the sacrificial patterns selectively with respect to the existing guiding pattern(s). This procures better dimensional control than the dry etching method (by plasma) employed in the prior art.

In a first embodiment, the method further comprises a step of formation on the substrate, in areas created by the removal of the sacrificial patterns, third patterns made of a third polymer material.

According to a development of this first embodiment, the third polymer material has a third chemical affinity with respect to the organic nano-objects, different from the second chemical affinity.

According to another development, the third polymer material has the first chemical affinity.

In a second embodiment, the method further comprises, between the step of formation of the second patterns and the step of removal of the sacrificial patterns, the following steps:
partially etching the sacrificial patterns so as to reduce the critical dimension of the sacrificial patterns, the sacrificial patterns being etched selectively with respect to said at least one first pattern and to the second patterns using a second wet etching method;
forming on the substrate, in areas created by the partial etching of the sacrificial patterns, fourth patterns made of a fourth polymer material.

According to a development of this second embodiment, the fourth polymer material has a fourth chemical affinity with respect to the organic nano-objects, different from the second chemical affinity.

According to another development, the fourth polymer material has the first chemical affinity.

According to another development, the third polymer material has the second chemical affinity.

In a third embodiment, the method further comprises, between the step of forming the fourth patterns and the step of removing the sacrificial patterns, the following steps:
partially etching the sacrificial patterns so as to reduce the critical dimension of the sacrificial patterns, the sacrificial patterns being etched selectively with respect to said at least one first pattern, to the second patterns and to the fourth patterns using a third wet etching method;
forming on the substrate, in areas created by the partial etching of the sacrificial patterns, fifth patterns made of a fifth polymer material.

According to a development of this third embodiment, the fourth polymer material has a fourth chemical affinity with respect to the organic nano-objects, different from the second chemical affinity, and the fifth polymer material has the second chemical affinity.

According to another development, the third polymer material has the first chemical affinity.

Apart from the characteristics that have been mentioned in the preceding paragraphs, the method for forming a chemical guiding structure according to the first aspect of the invention may have one or more complementary characteristics among the following, considered individually or according to all technically possible combinations thereof:
the first wet etching method, the second wet etching method and/or the third wet etching method are accomplished by means of a same chemical solution;
the sacrificial patterns are comprised of a silicon oxide; and
the chemical solution is a hydrofluoric acid solution.

A second aspect of the invention relates to a chemo-epitaxy method comprising the formation of a chemical guiding structure on a substrate using the formation method described above, the deposition of organic nano-objects on the chemical guiding structure and the assembly of the organic nano-objects.

The organic nano-objects may be chosen from among the domains of a block copolymer, DNA strands, DNA origamis and proteins.

The invention and the different applications thereof will be better understood on reading the description that follows and by examining the figures that accompany it.

### BRIEF DESCRIPTION OF THE FIGURES

Other characteristics and benefits of the invention will become clear from the description that is given thereof below, for indicative purposes and in no way limiting, with reference to the appended figures, among which:

FIG. 1, described previously, represents the steps of a chemo-epitaxy method according to the prior art;

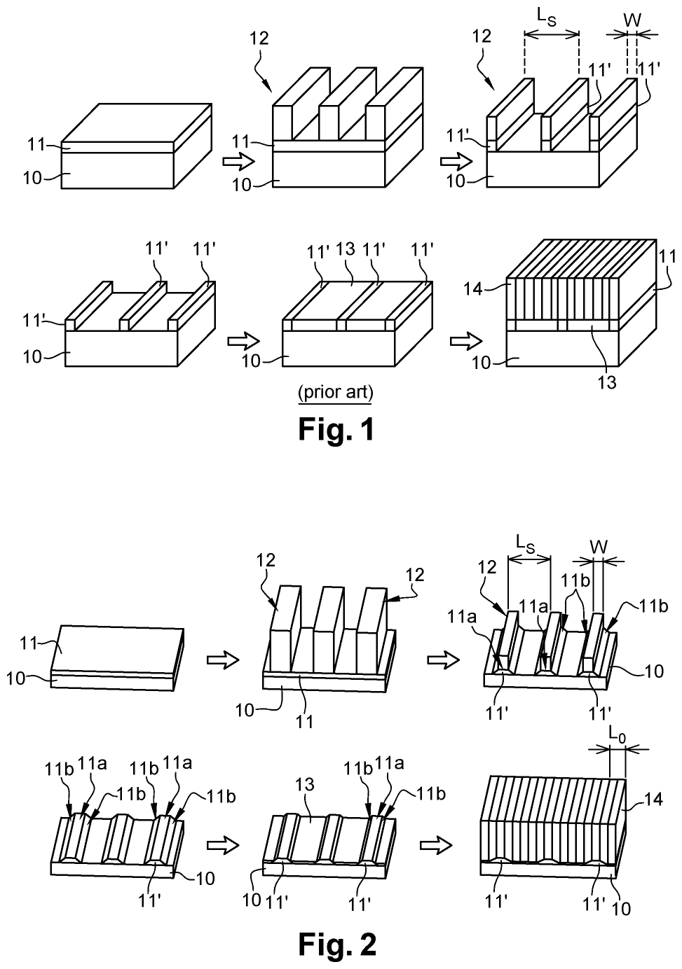

FIG. 2, described previously, represents an alternative of the chemo-epitaxy method according to FIG. 1;

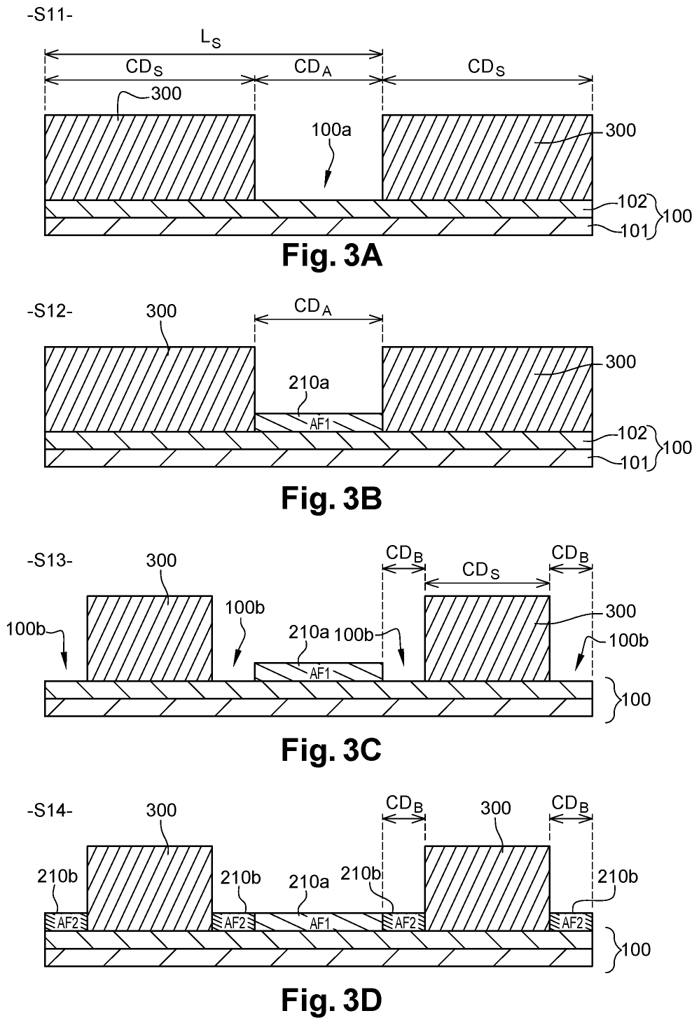

FIG. 3A, FIG. 3B, FIG. 3C, FIG. 3D, FIG. 3E and FIG. 3F represent the steps of a method for forming a chemical guiding structure, according to a first embodiment of the invention;

FIG. 4 schematically represents the assembly of a block copolymer deposited on the chemical guiding structure of FIG. 3F;

FIG. 5A, FIG. 5B, FIG. 5C, FIG. 5D, FIG. 5E, FIG. 5F, FIG. 5G and FIG. 5H represent the steps of a method for forming a chemical guiding structure, according to a second embodiment of the invention;

FIG. 6E, FIG. 6F, FIG. 6G, FIG. 6H, FIG. 6I and FIG. 6J represent, as complements to the steps of FIGS. 5A to 5D, the steps of a method for forming a chemical guiding structure, according to a third embodiment of the invention; and

FIG. 7 schematically represents the assembly of a block copolymer deposited on the chemical guiding structure of FIG. 6J.

For greater clarity, identical or similar elements are marked by identical reference signs in all of the figures.

### DETAILED DESCRIPTION

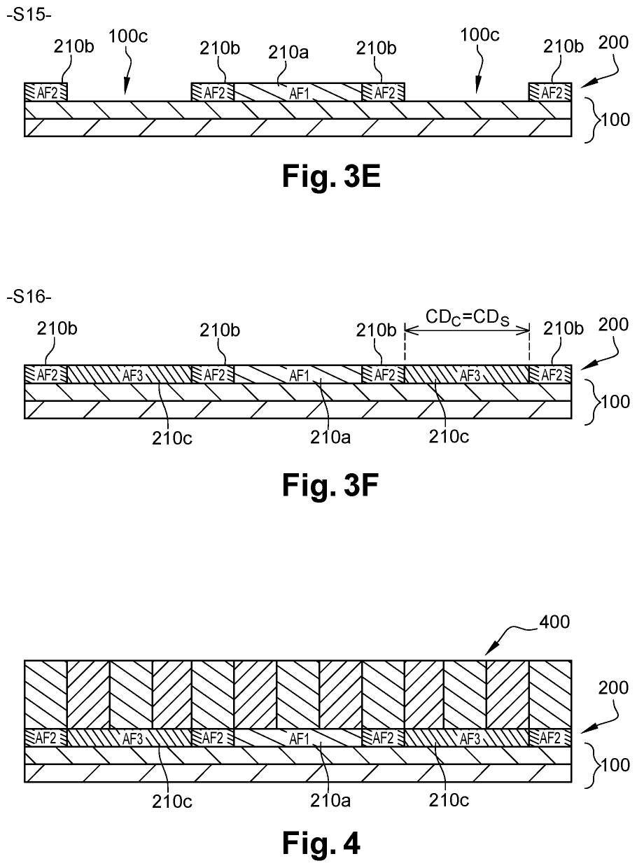

The method described hereafter in relation with FIGS. 3A-3F, 5A-5H and 6E-6J makes it possible to form a chemical guiding structure on a face of a substrate 100. A chemical guiding structure here designates a set of at least two polymer patterns arranged on distinct regions of the substrate 100 and having different chemical affinities, this set being repeated periodically on the surface of the substrate. A chemical contrast is thus created on the surface of the substrate 100. The surface of the substrate 100 may have a chemical affinity identical to one of the polymer patterns.

This chemical guiding (or contrast) structure is intended to be covered with organic nano-objects to assemble, within the scope of a method for directed self-assembly by chemo-epitaxy. The organic nano-objects may be the domains of a block copolymer, proteins, DNA strands or DNA origamis.

The method for forming a chemical guiding structure is described below in taking as example of application the self-assembly of a block copolymer, for example PS-b-PMMA. The chemical contrast makes it possible to direct (or “guide”) the organisation of the monomer blocks that compose the copolymer. Thus, the chemical affinities of the polymer patterns extend with respect to the blocks of the copolymer. These affinities may be chosen from among the following possibilities:
preferential affinity for any one of the blocks of the copolymer; or
neutral, that is to say with an equivalent affinity for each of the blocks of the copolymer.

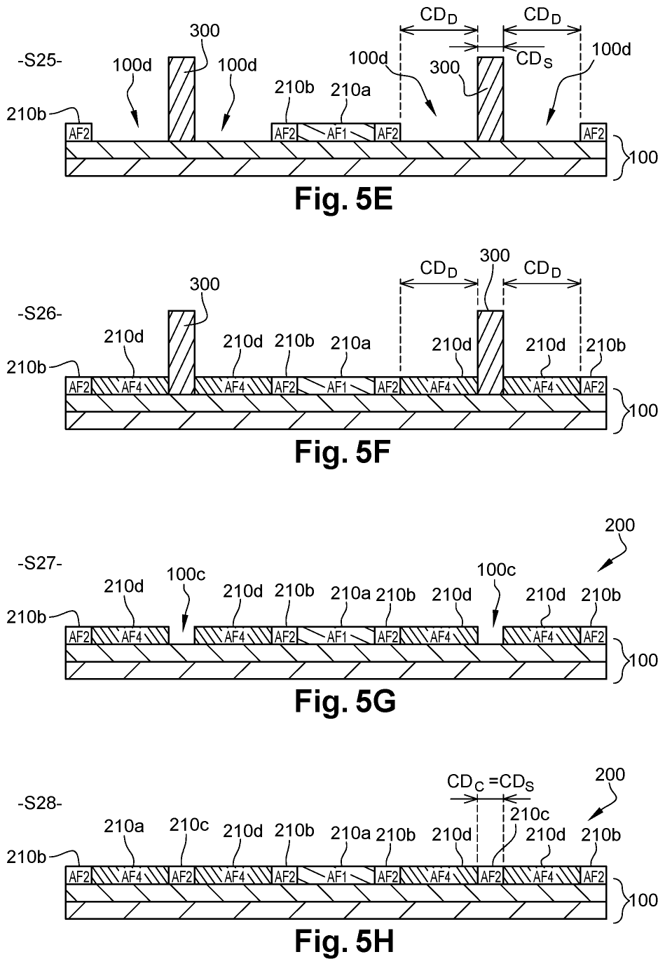

With reference to FIGS. 3E-3F, 5G-5H, 6I-6J, the chemical guiding structure 200 comprises one or more first guiding patterns 210a, second guiding patterns 210b and, according to the embodiments of the method, third guiding patterns 210c, fourth guiding patterns 210d and fifth guiding patterns 210e. The guiding patterns 210a-210e are distinct and arranged on the substrate 100, of which the surface is beneficially flat. In an embodiment, they are juxtaposed and may occupy all the surface of the substrate 100 (cf. FIGS. 3F, 5H & 6J).

The guiding patterns 210a-210e have the role of chemically (and differently) functionalising the substrate 100. They could thus also be qualified as functionalisation patterns. In a manner common to all the embodiments, each first guiding pattern 210a is comprised of a first polymer material having a chemical affinity AF1 (here with respect to the block copolymer). The second guiding patterns 210b are formed of a second polymer material having a chemical affinity AF2 different from the chemical affinity AF1 of the first polymer material.

A small difference in thickness, typically less than 10 nm, may exist between the different guiding patterns 210a-210e of the chemical guiding structure 200 or between the substrate 100 and the guiding patterns 210a-210e. This difference in thickness, forming a topographic contrast, does not however have a negative impact on the assembly of the block copolymer.

The substrate 100 may comprise a support layer 101, for example made of silicon, and a superficial layer 102 arranged on the support layer 101. The superficial layer 102 is, in an embodiment, a layer intended to form a hard mask, this hard mask being used later to etch the support layer 101 (within the scope of the method for directed self-assembly of the block copolymer). The superficial layer 102 is for example comprised of titanium nitride (TiN) or hafnium oxide (HfO₂).

In the description that follows, “grafting” of a polymer on a substrate is taken to mean the formation of covalent bonds between the substrate and the polymer chains. As a comparison, the cross-linking of a polymer involves the formation of several bonds between the polymer chains without necessarily the formation of covalent bonds with the substrate.

The critical dimension of a pattern hereafter designates the smallest dimension of this pattern in a plane parallel to the substrate 100.

FIGS. 3A to 3F are sectional views illustrating steps S11 to S16 of the method for forming a chemical guiding structure, according to a first embodiment of the invention.

The first step S11 of the method, illustrated by FIG. 3A, consists in forming on the substrate 100 sacrificial patterns 300, also called “mandrels” or “primary patterns”. The sacrificial patterns 300 are separated two by two by a free area (or a space) 100a of the surface of the substrate 100. In an embodiment, they have the form of lines which are parallel with each other.

The sacrificial patterns 300 are for example formed by deposition of a layer made of sacrificial material and patterning of the layer of sacrificial material by photolithography. The thickness of the layer of sacrificial material may be comprised between 100 nm and 200 nm. In an embodiment, the sacrificial material is chosen from among materials which may be easily etched and removed by wet etching, in a selective manner with respect to the substrate 100 and to the functionalisation polymer materials. As an example, hydrogen silsesquioxane (HSQ), silicon nitride (Si₃N₄), titanium (Ti), and silicon oxides, such as tetraethyl orthosilicate (TEOS) and silicon dioxide (SiO₂) may be cited.

In the sectional plane of FIG. 3A, the sacrificial patterns 300 beneficially have a repetition pitch L_{S} substantially equal to a multiple integer of the natural period L₀ of the block copolymer (L_{S}=n*L₀±10%, with n a non-zero natural integer), for example equal to 4*L₀ or 6*L₀ (i.e. 120 nm or 180 nm in the case of a block copolymer having a natural period L₀ of 30 nm, such as PS-b-PMMA). In order not to encumber FIG. 3A and the following figures, only two sacrificial patterns 300 have been represented. The method for forming a chemical guiding structure may however be accomplished with a greater number of sacrificial patterns 300.

The distance CD_{A} that separates two consecutive sacrificial patterns 300 is, in an embodiment, substantially equal to an odd number of half natural periods L₀/2 (CD_{A}=n1*L₀/2±10%, with n1 an odd natural integer), for example equal to 3*L₀/2 or 5*L₀/2 (i.e. 45 nm or 75 nm in the case of PS-b-PMMA). Finally, in an embodiment, the sacrificial patterns 300 have a critical dimension CD_{S} substantially equal to an odd number of half natural periods L₀/2 (CD_{S}=n2*L₀/2±10%, with n2=2*n−n1 an odd natural integer), for example equal to 5*L₀/2 or 7*L₀/2 (or 75 nm or 105 nm in the case of PS-b-PMMA). The critical dimension CD_{S} of the sacrificial patterns 300 here corresponds to the width of the lines, measured parallel to the surface of the substrate 100 in the sectional plane of FIG. 3A.

With reference to FIG. 3B, the method next comprises a step S12 of formation of one or more (as a function of the number of sacrificial patterns 300) first guiding patterns 210a on the substrate 100, between the sacrificial patterns 300. In an embodiment, each first guiding pattern 210a entirely covers the free area 100a of the substrate 100 situated between two consecutive sacrificial patterns 300. Each first guiding pattern 210a thus has a critical dimension (or width) equal to the distance CD_{A} separating two consecutive sacrificial patterns 300 (i.e. the width of the free area 100a).

In an embodiment, the formation of the first guiding pattern(s) 210a comprises the grafting of the first polymer material onto the substrate 100 (and, more specifically, onto the superficial layer 102 when said layer is present). To do so, the first polymer may be dissolved in a solvent to form a first polymer solution, then the first solution is deposited on the substrate 100 so as to cover entirely the space (that is to say the area of the substrate) situated between the sacrificial patterns 300. The first polymer solution then forms a film, the thickness of which may be comprised between 15 nm and 50 nm. In an embodiment, the deposition of the first solution on the substrate 100 is accomplished by spin-coating. It is followed by an operation of grafting of the first polymer, for example by annealing. The annealing is for example carried out at a temperature equal to 200° C., for a duration equal to 75 seconds, on a hot plate or in an furnace. A part of the first polymer in solution is then fixed to the substrate 100 and, in a superfluous manner, on the lateral walls of the sacrificial patterns 300. A rinsing operation using a solvent next makes it possible to eliminate the remaining part of the first polymer, which has not been grafted. This solvent is for example propylene glycol methyl ether acetate (PGMEA).

The sacrificial patterns 300 thus form a mask or stencil for localising the grafting of the first polymer onto the substrate 100. The thickness of the first guiding pattern 210a may be comprised between 3 nm and 7 nm (for example 4 nm in the aforementioned grafting conditions).

In an embodiment, the chemical affinity AF1 of the first polymer is neutral. The first polymer may notably be a random copolymer such as PS-r-PMMA.

At step S13 of FIG. 3C, the sacrificial patterns 300 are partially and selectively etched with respect to the substrate 100 and to the first guiding pattern 210a, so as to reduce the critical dimension CD_{S} of the sacrificial patterns 300. To do so, a wet etching method is employed. This etching method consists in exposing the sacrificial patterns 300 to a chemical solution, for example a hydrofluoric acid (HF) solution. Etching by wet process having an isotropic character, the dimensions of the sacrificial patterns 300 are reduced in a uniform manner.

The partial etching of the sacrificial patterns 300 frees two areas 100b of the surface of the substrate 100, arranged on either side of each sacrificial pattern 300 in the sectional plane of FIG. 3C. The etching conditions (time of exposure to the chemical solution, concentration of the chemical solution, etc.) are, in an embodiment, set such that each free area 100b of the substrate 100 has a width CD_{B} of around a half natural period L₀/2 of the block copolymer (CD_{B}=L₀/2±10%, i.e. 15 nm in the case of PS-b-PMMA). In other words, the critical dimension CD_{S} of the sacrificial patterns 300 is reduced by two half natural periods L₀/2.

Thus, step S13 of FIG. 3C is a step of trim etching the sacrificial patterns 300, accomplished by wet process, and not by dry process (plasma etching) as in methods of the prior art. Compared to dry etching, wet etching makes it possible to control the decrease in the critical dimension CD_{S} of the sacrificial patterns 300 more easily, because the etching rate may be controlled very precisely by adjusting the dilution of the HF solution. It is further simpler to implement. Furthermore, wet etching does not modify the surface properties of the substrate.

As an example, the substrate 100 is immersed for 1 min in a hydrofluoric acid (HF) bath of concentration equal to 1% to decrease by 30 nm the critical dimension of the sacrificial patterns 300 made of TEOS.

Step S14 of FIG. 3D consists in forming the second guiding patterns 210b, in the free areas 100b of the substrate 100 created by the partial etching of the sacrificial patterns 300. In an embodiment, each free area 100b of the substrate 100 is entirely covered by a second guiding pattern 210b. The second guiding patterns 210b then have a critical dimension equal to the width CD_{B} of the free areas 100b.

The second guiding patterns 210b are beneficially formed in the manner described in relation with FIG. 3B, that is to say by deposition on the substrate 100 of a second polymer solution in which the second polymer material is dissolved, grafting then rinsing. The second polymer is thus grafted onto the substrate 100 outside of the sacrificial patterns 300 and the first guiding pattern 210a. Although the second polymer solution covers the first guiding pattern 210a, the second polymer material does not replace or does not mix with the first polymer material during the grafting operation. The thickness of the second guiding patterns 210b (after annealing and rinsing) may be comprised between 3 nm and 10 nm (for example 4 nm).

The molar masses of the first and second polymers are beneficially less than 5 kg·mol⁻¹, in order to ensure a high grafting density at the level of the substrate 100. The polymer patterns are thus thin and compact.

In an embodiment, the chemical affinity AF2 of the second polymer (second guiding patterns 210b) is preferential for any one of the blocks of the copolymer, for example the PS block of the copolymer PS-b-PMMA. The second polymer may notably be a homopolymer, for example polystyrene (h-PS).

Finally, at step S15 of FIG. 3E, the sacrificial patterns 300 are removed selectively with respect to the substrate 100 and to the guiding patterns 210a-210b, in an embodiment, by wet etching using the same etching solution as at the step of trimming S13 the sacrificial patterns 300 (FIG. 3C). For example, sacrificial patterns 300 of critical dimension CD_{S} equal to 45 nm are totally etched by immersing the substrate 100 in a hydrofluoric acid (HF) bath of concentration equal to 1% for 5 min.

At the end of the removal step S15, only the first guiding pattern 210a and the second guiding patterns 210b then remain on the substrate 100. The surface of the substrate 100 comprises free (that is to say uncovered) areas 100c created by the removal of the sacrificial patterns 300.

The step S15 of removal of the sacrificial patterns 300 is beneficially followed by rinsing with solvent (water, PGMEA, etc.), in order to eliminate etching residues.

With reference to FIG. 3F, the method may comprise an additional step S16 of formation of third guiding patterns 210c on the substrate 100, as complements to the first and second guiding patterns 210a-210b. The third guiding patterns 210c are formed in the free areas 100c of the substrate 100 created by the removal of the sacrificial patterns 300. They are comprised of a third polymer material having a chemical affinity AF3 different from the chemical affinity AF2 of the second polymer material (second guiding patterns 210b). The chemical affinity AF3 of the third polymer may be neutral. In an embodiment, it is identical to the chemical affinity AF1 of the first polymer (first guiding pattern 210a).

Beneficially, the third polymer is identical to the first polymer. Only two different polymers are then employed in the method of FIGS. 3A-3F, which makes it particularly simple to implement.

Step S16 of formation of the third guiding patterns 210c may be accomplished in the same manner as step S12 of formation of the first guiding pattern 210a (or step S14 of formation of the second guiding patterns 210b) and comprises the grafting of the third polymer onto the substrate 100 outside of the guiding patterns 210a-210b. The third guiding patterns 210c beneficially have a critical dimension CD_{C} equal to the critical dimension CD_{S} of the sacrificial patterns 300 after the trimming step S13, i.e. an odd number of half natural periods L₀/2 (CD_{C}=(n2−2)*L₀/2±10%), for example 3*L₀/2 or 5*L₀/2.

The guiding structure 200 obtained at the end of FIG. 3F may be used in a method for directed self-assembly (DSA) of block copolymer, and more specifically in a chemo-epitaxy method, in order to generate patterns of very high resolution and density.

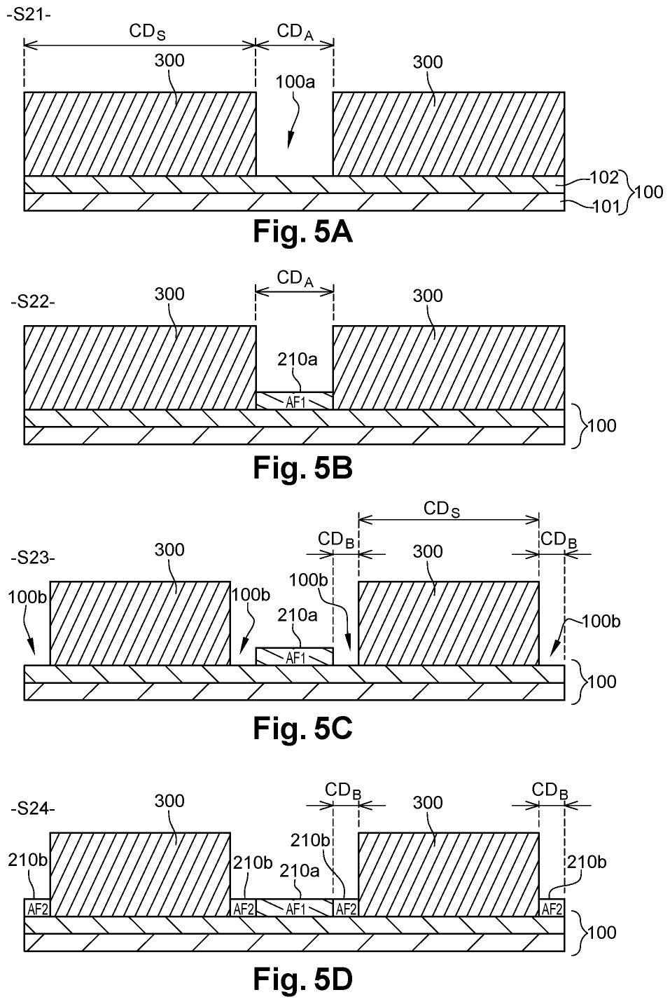

With reference to FIG. 4, the chemo-epitaxy method comprises (apart from the formation of the guiding structure 200) a step of deposition of a block copolymer 400 of lamellar morphology on the chemical guiding structure 200 and a step of assembly of the block copolymer 400, for example by thermal annealing. The block copolymer 400 may be a di-block (two monomers) or multi-block (more than two monomers) copolymer, a mixture of polymers, a mixture of copolymers or even the mixture of a copolymer and a homopolymer. The domains of the copolymer are after assembly oriented perpendicularly to the substrate 100, thanks to the first guiding pattern 210a and to the third guiding patterns 210c (of which the affinity is neutral).

The block copolymer 400 may be a standard block copolymer (L₀≥25 nm) or a “high-X” block copolymer (L₀<25 nm). It may notably be chosen from among the following:
PS-b-PMMA: polystyrene-block-polymethylmethacrylate;
PS-b-PMMA, of which at least one of the two blocks is chemically modified to decrease the natural period of the copolymer;
PS-b-PDMS: polystyrene-block-polydimethylsiloxane;
PS-b-PLA: polystyrene-block-polylactic acid;
PS-b-PEO: polystyrene-block-polyethylene oxide;
PS-b-PMMA-b-PEO: polystyrene-block-polymethylmethacrylate-block-polyethylene oxide;
PS-b-P2VP: polystyrene-block-poly(2vinylpyridine);
PS-b-P4VP: polystyrene-block-poly(4vinylpyridine);
PS-b-PFS: poly(styrene)-block-poly(ferrocenyldimethylsilane);
PS-b-PI-b-PFS: poly(styrene)-block-poly(isoprene)-block-poly(ferrocenyldimethylsilane);
PS-b-P(DMS-r-VMS): polystyrene-block-poly(dimethylsiloxane-r-vinylmethylsiloxane);
PS-b-PMAPOSS: polystyrene-block-poly(methyl acrylate)POSS;
PDMSB-b-PS: poly(1,1-dimethylsilacyclobutane)-block-polystyrene;
PDMSB-b-PMMA: poly(1,1-dimethylsilacyclobutane)-block-poly(methyl methacrylate);
PMMA-b-PMAPOSS: poly(methylmethacrylate)-block-poly(methyl acrylate)POSS;
P2VP-b-PDMS: poly(2-vinylpyridine)-block-poly(dimethyl siloxane);
PTMSS-b-PLA: poly(trimethylsilylstyrene)-block-poly(D,L-lactide);
PTMSS-b-PDLA: poly(trimethylsilylstyrene)-block-poly(D-lactic acid);
PTMSS-b-PMOST: poly(trimethylsilylstyrene)-block-poly(4-methoxystyrene);
PLA-b-PDMS: poly(D,L-lactide)-block-poly(dimethylsiloxane);
PAcOSt-b-PSi2St: poly(4-acetoxystyrene)-block-poly(4-(Bis(trimethylsilyl)methyl)styrene);
1,2-PB-b-PDMS: 1,2-polybutadiene-block-poly(dimethyl siloxane);
PtBS-b-PMMA: poly(4-tert-butylstyrene)-block-poly(methyl methacrylate);
PCHE-b-PMMA: polycyclohexane-block-poly(methyl methacrylate);
MH-b-PS: maltoheptaose-block-polystyrene.

The chemical guiding structure 200 of FIG. 3E may also be used for the assembly of the block copolymer 400. In other words, the step S16 of formation of the third guiding patterns 210c is optional. To increase the assembly kinetic and/or reduce the number of organisation defects, it is however desirable that the substrate 100 has (on the surface) a neutral chemical affinity.

The formation of the third guiding patterns 210c is beneficial when the substrate does not have the desired chemical affinity and/or when it is sought to obtain a guiding structure as flat as possible.

A superficial layer made of titanium nitride (TiN) is hydrophilic and consequently has a preferential chemical affinity for the PMMA block. The method of FIGS. 3A-3F may thus be adapted so that the free areas 100c of the substrate 100 have a width equal to half of the natural period of the block copolymer (CD_{C}=0.5*L₀), i.e. the critical dimension of the domains of the PMMA block. The first guiding pattern 210a and the second guiding patterns 210b may then have the same neutral chemical affinity but be formed of different polymer materials. In the case of a substrate having a preferential affinity for any one of the blocks of the copolymer (for example the PMMA block), the method may alternatively comprise only a single step of deposition of a polymer material having a neutral chemical affinity AF1, after the step of wet etching of the sacrificial patterns and before the step of removal of the sacrificial patterns (of critical dimension CD_{S}=0.5*L₀).

FIGS. 5A to 5H represent steps S21 to S28 of the method for forming a chemical guiding structure, according to a second embodiment of the invention.

Steps S21-S24 of FIGS. 5A-5D are identical to steps S11-S14 described in relation with FIGS. 3A-3D and end up in a structure (illustrated by FIG. 5D) very similar to that of FIG. 3D. The only difference between FIGS. 3A-3D and FIGS. 5A-5D is the value of the critical dimension CD_{S} of the sacrificial patterns 300. The critical dimension CD_{S} of the sacrificial patterns 300 in FIGS. 5A-5D is greater than that of the sacrificial patterns 300 in FIGS. 3A-3D. It is for example equal to 9*L₀/2 (i.e. CD_{S}=135 nm in the case of PS-b-PMMA) before the etch trim step S23 and to 7*L₀/2 (i.e. CD_{S}=105 nm in the case of PS-b-PMMA) after the etch trim step S23. As previously, the distance CD_{A} that initially separates two consecutive sacrificial patterns 300 may be equal to 3*L₀/2 (45 nm) and the repetition pitch L_{S} of the sacrificial patterns 300 may be equal to 6*L₀ (180 nm).

Thus, the critical dimension CD_{S}, the spacing CD_{A} and the repetition pitch L_{S} of the sacrificial patterns 300 are defined in the same manner as previously, as a function of a natural whole integer (odd) of half natural periods L₀/2 or of a natural whole integer (non-zero) of natural periods L₀. The second guiding patterns 210b also have in this second embodiment a critical dimension CD_{B} of around a half natural period L₀/2.

Step S25 of FIG. 5E is a second step of trimming the sacrificial patterns 300, by wet etching selective with respect to the substrate 100 and to the guiding patterns 210a-210b. In an embodiment, the sacrificial patterns 300 are etched partially by employing the same chemical solution as at the first trimming step S23. The critical dimension CD_{S} of the sacrificial patterns 300 is beneficially reduced until reaching a value of around a half natural period L₀/2.

This second partial etching of the sacrificial patterns 300 generates new free areas 100d on the surface of the substrate 100. These free areas 100d, arranged on either side of the sacrificial patterns 300, have a width CD_{D} equal to an odd number of half natural periods L₀/2 (CD_{D}=n3*L₀/2±10%, with n3=(n2−2−1)/2 an odd natural integer).

With reference to FIG. 5F, the method next comprises a step of formation of fourth guiding patterns 210d in the free areas 100d of the substrate 100. The fourth guiding patterns 210d are formed of a fourth polymer material having a chemical affinity AF4 different from the chemical affinity AF2 of the second polymer material (second guiding patterns 210b). The chemical affinity AF4 of the fourth polymer may be neutral. In an embodiment, it is identical to the chemical affinity AF1 of the first polymer (first guiding pattern 210a). Beneficially, the fourth polymer is identical to the first polymer.

Step S26 of formation of the fourth guiding patterns 210d may be accomplished in the same manner as step S22 of formation of the first guiding pattern 210a and comprise the grafting of the fourth polymer onto the substrate 100 outside of the sacrificial patterns 300 and the guiding patterns 210a-210b. The fourth guiding patterns 210d beneficially have a critical dimension equal to the width CD_{D} of the free areas 100d. The critical dimension CD_{D} of the fourth guiding patterns 210d is, in an embodiment, equal to the critical dimension CD_{A} of the first guiding pattern 210a (hence n3=n1), i.e. here 3*L₀/2 (45 nm).

At step S27 of FIG. 5G, the sacrificial patterns 300 are removed, in an embodiment in the manner described in relation with FIG. 3E (that is to say by wet etching), thus generating the free areas 100c.

Finally, in S28 (cf. FIG. 5H), the third guiding patterns 210c are beneficially formed on the substrate 100 in the free areas 100c created by the removal of the sacrificial patterns 300, as has been described in relation with FIG. 3F.

Thus, in this second embodiment, the third guiding patterns 210c have a critical dimension CD_{C} equal to the critical dimension CD_{S} of the sacrificial patterns 300 after the second trimming step S25, i.e. here a half natural period L₀/2. Moreover, the third polymer forming the third guiding patterns 210c has the same chemical affinity (AF2) as the second polymer (second guiding patterns 210b), that is to say a preferential affinity for one of the blocks of the copolymer. Beneficially, the third polymer is identical to the second polymer.

In a manner analogous to FIGS. 3E-3F, each of the chemical guiding structures 200 represented in FIGS. 5G-5H may be used for the assembly of the block copolymer 400.

For a same repetition pitch of the sacrificial patterns 300 (e.g. L_{S}=6*L₀), the guiding structure 200 of FIG. 5H (or of FIG. 5G) comprises a greater number of guiding patterns than that represented by FIG. 3F (or FIG. 3E). It consequently enables an assembly of the block copolymer that is more rapid and/or less sensitive to organisation defects.

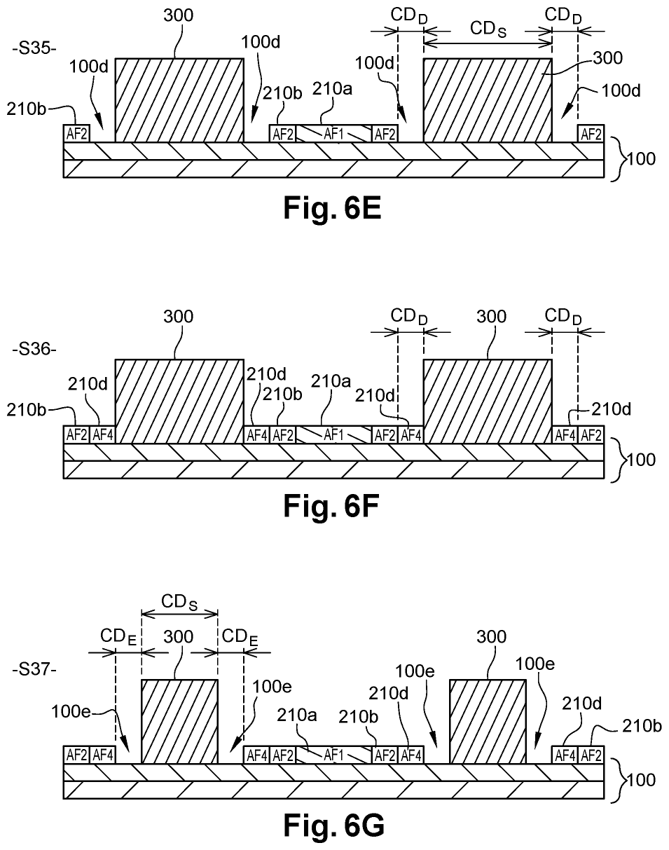

FIGS. 6E to 6J represent steps S35 to S40 of the method for forming a chemical guiding structure, according to a third embodiment of the invention. These steps S35-S40 are accomplished following steps S21-S24 represented by FIGS. 5A-5D and consequently replace steps S25-S28 of FIGS. 5E-5H.

Step S35 of FIG. 6E is a second step of trimming the sacrificial patterns 300, after the first trimming step S23 of FIG. 5C. This second trimming step S35 is accomplished by wet etching, in an embodiment employing the same chemical solution as at the first trimming step S23. It is moreover identical to the second trimming step S25 of the method according to the second embodiment of the invention (FIG. 5E), with the difference that the critical dimension CD_{S} of the sacrificial patterns 300 is here reduced by only two half natural periods L₀/2.

At step S36 of FIG. 6F, the fourth guiding patterns 210d are formed on the substrate 100 (in the free areas 100d) in the same manner as in step S26 of FIG. 5F. However, in this third embodiment of the method, they have a critical dimension CD_{D} of around a half natural period (CD_{D}=L₀/2±10%).

The chemical affinity AF4 of the fourth polymer (fourth guiding patterns 210d) is different from the chemical affinity AF2 of the second polymer (second guiding patterns 210b). It is beneficially preferential for a first “A” block of the copolymer (e.g. the PS block), whereas the chemical affinity AF2 of the second polymer is preferential for a second “B” block of the copolymer (e.g. the PMMA block).

Step S37 of FIG. 6G is a third step of trimming the sacrificial patterns 300 by wet etching. The sacrificial patterns 300 are etched selectively with respect to the substrate 100 and to the guiding patterns 210a, 210b and 210d, in an embodiment employing the same chemical solution as in the first and second trimming steps S23 and S35. Once again, the critical dimension CD_{S} of the sacrificial patterns 300 is, in an embodiment, reduced by two half natural periods L₀/2. The trimming of the sacrificial patterns 300 generates on the surface of the substrate 100 two new free areas 100e, arranged on either side of each sacrificial pattern 300. The free areas 100e here have a width CD_{E} equal to around a half natural period (CD_{E}=L₀/2±10%).

Step S38 of FIG. 6H consists in forming fifth guiding patterns 210e on the substrate 100, in the free areas 100e obtained at the end of the third step S37 of trimming the sacrificial patterns 300.

The fifth guiding patterns 210e are formed of a fifth polymer material having the chemical affinity AF2 of the second polymer material (second guiding patterns 210b), that is to say a preferential affinity for the “B” block of the copolymer. Beneficially, the fifth polymer is identical to the second polymer.

Step S38 of formation of the fifth guiding patterns 210e may be accomplished in the same manner as step S22 of formation of the first guiding pattern 210a and comprise the grafting of the fifth polymer onto the substrate 100 outside of the sacrificial patterns 300 and the guiding patterns 210a, 210b and 210d. The fifth guiding patterns 210e beneficially have a critical dimension equal to the width CD_{E} of the free areas 100e and to the critical dimension CD_{D} of the second guiding patterns 210b, i.e. around a half natural period (CD_{E}=L₀/2±10%).

At step S39 of FIG. 6I, the sacrificial patterns 300 are next removed (in an embodiment by wet etching).

Finally, in S40 (cf. FIG. 6J), the third guiding patterns 210c are beneficially formed on the substrate 100 in the free areas 100c created by the removal of the sacrificial patterns 300, for example by grafting the third polymer thereon.

The third guiding patterns 210c have, in this third embodiment, a critical dimension CD_{C} equal to the critical dimension CD_{S} of the sacrificial patterns 300 after the third trimming step S37, i.e. an odd number of half natural periods L₀/2 (CD_{C}=(n2−2*3)*L₀/2±10%), for example 3*L₀/2. The chemical affinity AF3 of the third polymer may be neutral. In an embodiment, it is identical to the chemical affinity AF1 of the first polymer (first guiding pattern 210a). Beneficially, the third polymer is identical to the first polymer (first guiding pattern 210a).

In the first embodiment (FIGS. 3A-3F) and the third embodiment (FIGS. 5A-5D and 6E-6J) of the method, the sacrificial patterns 300 are beneficially dimensioned such that the critical dimension CD_{S} of the sacrificial patterns 300 is, after the last trimming step (S13 or S37), equal to the distance CD_{A} that initially separates two consecutive sacrificial patterns 300. The critical dimension CD_{C} of the third guiding patterns 210c is then equal to that of the first guiding pattern 210a (CD_{C}=CD_{A}).

In a manner analogous to FIGS. 3E-3F and FIGS. 5G-5H, each of the chemical guiding structures 200 represented in FIGS. 6I-6J may be used for the assembly of the block copolymer 400.

The chemical guiding structure of FIG. 6J may be three-tone, notably when the following conditions are met:
the first polymer (first guiding pattern 210a) and/or the third polymer (third guiding patterns 210c) have a neutral chemical affinity AF1/AF3;
the second polymer (second guiding patterns 210b) and the fifth polymer (fifth guiding patterns 210e) have a preferential chemical affinity AF2 for the “B” block of the copolymer;
the fourth polymer (fourth guiding patterns 210d) has a preferential chemical affinity AF4 for the “A” block of the copolymer.

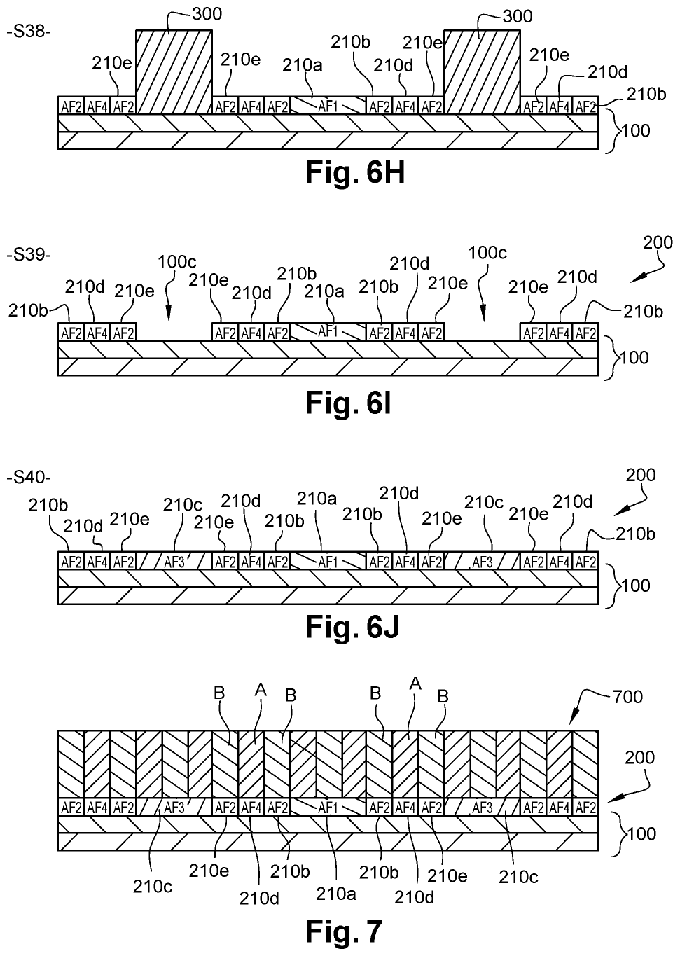

FIG. 7 schematically represents the assembly of a di-block (A-b-B) block copolymer 700 on the three-tone chemical guiding structure of FIG. 6J. The fourth guiding patterns 210d are covered by domains of the “A” block. The second guiding patterns 210b and fifth guiding patterns 210e are covered by domains of the “B” block. All of the domains of the “A” block and the “B” block are oriented perpendicularly to the substrate 100 thanks to the first guiding pattern 210a and to the third guiding patterns 210c of which the affinity is neutral.

Such a three-tone chemical guiding structure guarantees a high assembly kinetic and/or a very small number of organisation defects.

The molar masses of the third, fourth and/or fifth polymers are beneficially less than 5 kg·mol−1, in order to ensure a high grafting density at the level of the substrate 100. The polymer patterns are thus thin and compact.

The method for forming a chemical guiding structure described above is particularly beneficial because it ensures precise control of the critical dimension of the guiding patterns. The trimming of the sacrificial patterns 300 (by wet etching) is facilitated by the fact that the sacrificial patterns initially have (that is to say before etching) a large critical dimension CD_{S}, typically greater than 5*L₀/2. The formation method further procures total freedom in the choice of chemical affinities, because the deposited polymer materials do not undergo any treatment liable to modify their chemical affinity. Finally, the grafting of polymer material is a particularly simple technique to implement, which enables compact and homogenous polymer patterns to be obtained.

The formation method is not limited to the embodiments described with reference to FIGS. 3, 5 and 6, many alternatives and modifications will become clear to those skilled in the art. In particular, the guiding patterns 210a-210e may have other critical dimension values and the polymer materials may have other chemical affinities or compositions than those described previously. Similarly, other block copolymers could be used.

Finally, although it has been described considering the self-assembly of a block copolymer, the method for forming a chemical guiding structure may be employed for the self-assembly by chemo-epitaxy of any type of nano-object. The chemical affinities AF1-AF4 of the polymer materials are defined with respect to the nano-objects to assemble.

1. A method for forming a chemical guiding structure intended for the self-assembly of organic nano-objects by chemo-epitaxy, the method comprising:
forming on a substrate sacrificial patterns having a critical dimension in a plane parallel to the substrate;
forming on the substrate, between the sacrificial patterns, at least one first pattern made of a first polymer material, the first polymer material having a first chemical affinity with respect to the organic nano-objects;
partially etching the sacrificial patterns so as to reduce the critical dimension of the sacrificial patterns, the sacrificial patterns being etched selectively with respect to said at least one first pattern using a first wet etching method;
forming on the substrate, in areas created by the partial etching of the sacrificial patterns, second patterns made of a second polymer material, the second polymer material having a second chemical affinity with respect to the organic nano-objects, different from the first chemical affinity; and
removing the sacrificial patterns.

2. The method according to claim 1, further comprising forming on the substrate, in areas created by the removal of the sacrificial patterns, third patterns made of a third polymer material.

3. The method according to claim 2, wherein the third polymer material has a third chemical affinity with respect to the organic nano-objects, different from the second chemical affinity.

4. The method according to claim 2, wherein the third polymer material has the first chemical affinity.

5. The method according to claim 1, further comprising, between the step of formation of the second patterns and the step of removal of the sacrificial patterns,
partially etching the sacrificial patterns so as to reduce the critical dimension of the sacrificial patterns, the sacrificial patterns being etched selectively with respect to said at least one first pattern and to the second patterns using a second wet etching method;
forming on the substrate, in areas created by the partial etching of the sacrificial patterns, fourth patterns made of a fourth polymer material.

6. The method according to claim 5, wherein the fourth polymer material has a fourth chemical affinity with respect to the organic nano-objects, different from the second chemical affinity.

7. The method according to claim 5, wherein the fourth polymer material has the first chemical affinity.

8. The method according to claim 5, further comprising, between the step of formation of the fourth patterns and the step of removal of the sacrificial patterns,
partially etching the sacrificial patterns so as to reduce the critical dimension of the sacrificial patterns, the sacrificial patterns being etched selectively with respect to said at least one first pattern, to the second patterns and to the fourth patterns using a third wet etching method;
forming on the substrate, in areas created by the partial etching of the sacrificial patterns, fifth patterns made of a fifth polymer material.

9. The method according to claim 8, wherein the fourth polymer material has a fourth chemical affinity with respect to the organic nano-objects, different from the second chemical affinity, and the fifth polymer material has the second chemical affinity.

10. The method according to claim 8, wherein the first wet etching method, the second wet etching method and the third wet etching method are accomplished by means of a same chemical solution.

11. The method according to claim 1, wherein the sacrificial patterns are comprised of a silicon oxide.

12. A method for chemo-epitaxy comprising:
forming a chemical guiding structure on a substrate using a method according to claim 1;
depositing organic nano-objects on the chemical guiding structure; and
assembling the organic nano-objects.

13. The method according to claim 1, wherein the organic nano-objects are chosen from among the domains of a block copolymer, DNA strands, DNA origamis and proteins.
